(19) United States
(12) Patent Application Publication
(10) Pub. No.: US 2025/0258075 A1
(43) Pub. Date: Aug. 14, 2025

(54) ELECTRODE CATALYST LAYER EVALUATION DEVICE, ELECTRODE CATALYST LAYER EVALUATION METHOD, AND PROGRAM

(71) Applicant: HONDA MOTOR CO., LTD., Tokyo (JP)

(72) Inventors: Shinya SATO, Saitama (JP); Naoki KUSHITANI, Saitama (JP); Takanori IGARASHI, Saitama (JP)

(21) Appl. No.: 19/021,217

(22) Filed: Jan. 15, 2025

(30) Foreign Application Priority Data
Feb. 9, 2024 (JP) 2024-018898

(51) Int. Cl. G01N 3/42; G01R 27/26

(52) U.S. Cl. CPC G01N 3/42; G01R 27/2623; G01N 2203/0064; G01N 2203/0078; G01N 2203/0286

(57) ABSTRACT

To provide an electrode catalyst layer evaluation device, an electrode catalyst layer evaluation method, and a program, which are capable of reducing cost and man-hours. The electrode catalyst layer evaluation device includes the acquisition unit that acquires the hardness and loss tangent tan δ of the electrode catalyst layer of a fuel cell, and the crack occurrence rate estimation unit that estimates the crack occurrence rate of the electrode catalyst layer, based on the hardness and loss tangent tan δ acquired by the acquisition unit.

This application is based on and claims the benefit of priority from Japanese Patent Application No. 2024-018898, filed on 9 Feb. 2024, the content of which is incorporated herein by reference.

### BACKGROUND OF THE INVENTION

### Field of the Invention

The present invention relates to an electrode catalyst layer evaluation device, an electrode catalyst layer evaluation method, and a program.

### Related Art

Conventionally, in the catalyst layer of polymer electrolyte fuel cells, there is known technology for inspecting cracks that occur during the process of coating and drying the so-called catalyst ink. Patent Document 1 is an example of such technology. Patent Document 1 discloses an inspection device that includes: a diffusion illumination unit; a mechanism that places a mask in proximity to a diffusion front; a camera that captures an image of diffused light coming from the diffusion front and passing through the inspection object coated with the electrode via the aperture of the mask; and a mechanism that binarizes the image and determines the acceptability of coating defects.

Patent Document 1: Japanese Unexamined Patent Application, Publication No. 2016-225059

### SUMMARY OF THE INVENTION

However, with the evaluation (inspection) method disclosed in Patent Document 1, each evaluation requires the preparation of samples, inspection devices, and other resources, which results in additional man-hours. Consequently, there is a need for an evaluation method capable of reducing the cost and man-hours involved in evaluation.

The present invention aims to provide an electrode catalyst layer evaluation device, an electrode catalyst layer evaluation method, and a program, which are capable of further reducing cost and man-hours.

(1) An electrode catalyst layer evaluation device of the present invention includes: an acquisition unit that acquires hardness and loss tangent tan δ of an electrode catalyst layer of a fuel cell; and a crack occurrence rate estimation unit that estimates a crack occurrence rate of the electrode catalyst layer, based on the hardness and the loss tangent tan δ acquired by the acquisition unit.

The electrode catalyst layer evaluation device as described in (1) is capable of further reducing cost and man-hours.

(2) With the electrode catalyst layer evaluation device as described in (1), the crack occurrence rate estimation unit estimates the crack occurrence rate of the electrode catalyst layer, based on pre-obtained correlation information between the hardness, the loss tangent tan δ, and the crack occurrence rate.

The electrode catalyst layer evaluation device as described in (2) is capable of reducing cost and man-hours while conducting evaluations more easily and with higher accuracy.

(3) The electrode catalyst layer evaluation device as described in (1) or (2) further includes a measurement unit that measures the hardness and the loss tangent tan δ of the electrode catalyst layer, and the acquisition unit acquires the hardness and the loss tangent tan δ from the measurement unit.

The electrode catalyst layer evaluation device as described in (3) is capable of reducing cost and man-hours while conducting evaluation more easily and with higher accuracy.

(4) With the electrode catalyst layer evaluation device as described in (3), the measurement unit is a nanoindentation tester.

The electrode catalyst layer evaluation device as described in (4) is capable of reducing cost and man-hours while conducting evaluation even more easily and with higher accuracy.

(5) An electrode catalyst layer evaluation method of the present invention includes: an acquiring step of acquiring hardness and loss tangent tan δ of an electrode catalyst layer of a fuel cell; and a crack occurrence rate estimating step of estimating a crack occurrence rate of the electrode catalyst layer, based on the hardness and the loss tangent tan δ.

The electrode catalyst layer evaluation method as described in (5) is capable of further reducing cost and man-hours.

(6) A program of the present invention causes a computer to execute: an acquisition function to acquire hardness and loss tangent tan δ of an electrode catalyst layer of a fuel cell; and a crack occurrence rate estimation function to estimate a crack occurrence rate of the electrode catalyst layer, based on the hardness and the loss tangent tan δ.

The program as described in (6) is capable of further reducing cost and man-hours.

According to the present invention, an electrode catalyst layer evaluation device, an electrode catalyst layer evaluation method, and a program, which are capable of further reducing cost and man-hours, can be provided.

### BRIEF DESCRIPTION OF THE DRAWINGS

FIG. 1 is a schematic diagram illustrating the general structure of an electrode catalyst layer evaluation device according to one embodiment of the present invention;

FIG. 2 is a block diagram illustrating the functional configuration of the electrode catalyst layer evaluation device according to one embodiment of the present invention;

FIG. 3 is an example diagram illustrating a correlation map between hardness, tan δ, and a crack occurrence rate according to one embodiment of the present invention; and

FIG. 4 is a flowchart illustrating the procedure of an electrode catalyst layer evaluation method according to one embodiment of the present invention.

### DETAILED DESCRIPTION OF THE INVENTION

### <Electrode Catalyst Layer Evaluation Device>

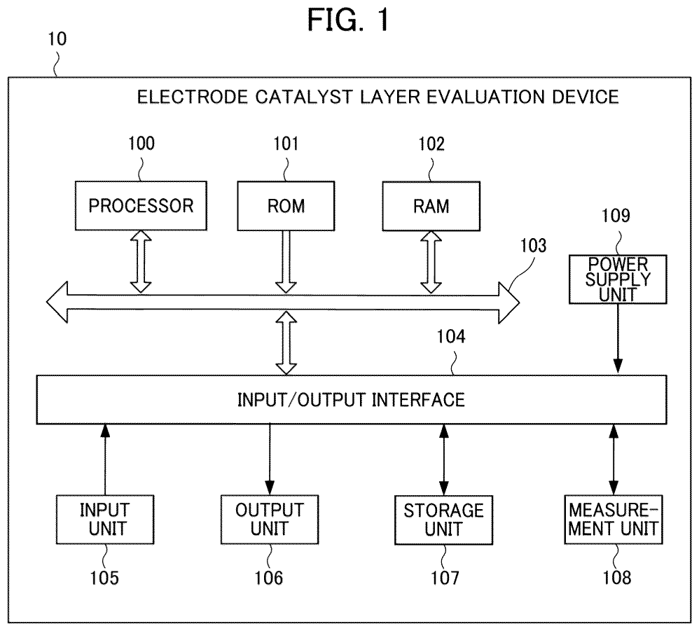

Hereinafter, an electrode catalyst layer evaluation device 10 according to one embodiment of the present invention will be described with reference to FIGS. 1 to 3. The electrode catalyst layer evaluation device 10 is a device for evaluating the electrode catalyst layer of a fuel cell as a sample. The fuel cell may be, for example, a polymer electrolyte fuel cell. The electrode catalyst layer is described herein as the catalyst layer included in the electrode of a polymer electrolyte fuel cell. The electrode catalyst layer evaluation device 10 according to one embodiment of the present invention conducts evaluation by estimating the crack occurrence rate of the electrode catalyst layer of the fuel cell. The crack occurrence rate refers to the occupancy rate of cracks within the surface of the object being measured. The electrode catalyst layer evaluation device 10 estimates the crack occurrence rate in order to evaluate cracks that occur during the manufacturing of the electrode of the fuel cell.

An example of the hardware configuration of the electrode catalyst layer evaluation device 10 according to one embodiment of the present invention is described below with reference to FIG. 1. The electrode catalyst layer evaluation device 10 is a device that evaluates the crack occurrence rate of the electrode catalyst layer, based on hardness and loss tangent tan δ. As illustrated in FIG. 1, the electrode catalyst layer evaluation device 10 includes a processor 100, a read-only memory (ROM) 101, a random access memory (RAM) 102, a bus 103, an input/output interface 104, an input unit 105, an output unit 106, a storage unit 107, a measurement unit 108, and a power supply unit 109.

The processor 100 is the central component of a computer that executes computation and control processing necessary for operating the electrode catalyst layer evaluation device 10, and executes various computation and processing.

The processor 100 controls each part of the electrode catalyst layer evaluation device 10 to implement various functions, based on programs such as firmware, system software, and application software stored in the ROM 101 or the RAM 102. The processor 100 executes processing, based on the programs. Some or all of the programs may be embedded within the circuitry of the processor 100.

The processor 100, the ROM 101, and the RAM 102 are interconnected via the bus 103. The input/output interface 104 is also connected to the bus 103. The input/output interface 104 is further connected to the input unit 105, the output unit 106, the storage unit 107, the measurement unit 108, and the power supply unit 109.

The input unit 105 and the output unit 106 are user interfaces electrically connected to the input/output interface 104 through a wired or wireless connection. The input unit 105 is configured as a keyboard, mouse, or similar device to input various types of information in response to user's instruction operations. The output unit 106 is configured as a display that displays images or a speaker that amplifies sounds, thereby providing images and sounds.

The storage unit 107 is an auxiliary storage device, such as a hard disk drive (HDD) or solid state drive (SSD). The storage unit 107 stores various types of information, including programs and setting values related to various processing. For example, the storage unit 107 stores a program for calculating hardness, elastic modulus, and dynamic viscoelasticity, which will be described later, as well as data on pre-established correlation information between hardness, loss tangent tan δ, and crack occurrence rate of the electrode catalyst layer of the fuel cell. Details of the correlation information will be described later.

The measurement unit 108 is configured to measure the hardness, elastic modulus, and dynamic viscoelasticity of the sample. The measurement unit 108 is composed of, for example, various measurement devices capable of measuring hardness, elastic modulus, and dynamic viscoelasticity. The measurement unit 108 according to the present embodiment is a nanoindentation tester capable of measuring hardness, elastic modulus, and dynamic viscoelasticity. The nanoindentation tester is also known as a nanoindenter or microhardness tester. The measurement unit 108, even when serving as a nanoindentation tester, is capable of conducting simpler and more accurate measurements, even in a case where the electrode catalyst layer serving as a sample is a thin film. The measurement unit 108 is not limited to a nanoindentation tester and may be composed of a known hardness tester and dynamic viscoelasticity measuring device.

The measurement unit 108 according to the present embodiment is capable of measuring hardness, elastic modulus, and dynamic viscoelasticity of a sample, using the nanoindentation method. The measurement unit 108 includes, for example, a sample stage (not illustrated) for fixing a sample, an indenter (not illustrated) of a triangular pyramid shape, a drive unit (not illustrated) that moves the indenter relative to the sample stage, a control unit (not illustrated) that controls the drive unit, and a detection unit capable of detecting load and displacement.

The power supply unit 109, which is connected to an external power source, is configured to supply power to each part of the electrode catalyst layer evaluation device 10. The configuration capable of supplying power from the power source is not limited to this, and may be a battery.

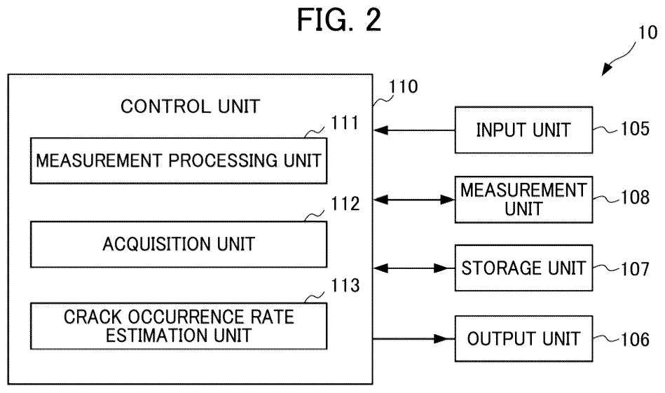

Next, the functional configuration of the electrode catalyst layer evaluation device 10 will be described with reference to FIG. 2. The control unit 110, which executes various control functions of the electrode catalyst layer evaluation device 10, is implemented by causing the processor 100, which executes computational processing described below, to execute programs stored in the ROM 101, the RAM 102, the storage unit 107, etc. The control unit 110 of the present embodiment includes a measurement processing unit (measurement processing function) 111, an acquisition unit (acquisition function) 112, and a crack occurrence rate estimation unit (crack occurrence rate estimation function) 113.

The measurement processing unit 111 executes measurement control and calculation processing. During the execution of measurement control, the measurement processing unit 111 controls the measurement operation of the measurement unit 108 to measure the hardness and loss tangent tan δ of the electrode catalyst layer of the fuel cell. For example, the measurement processing unit 111 according to the present embodiment drives the drive unit, based on load information and displacement information detected by the detection unit, such that the indenter presses into the sample, and the measurement operation conforms to the nanoindentation method or similar, thereby acquiring the drive information, load information, and displacement information of the drive unit.

Even in a case where the measurement unit 108 is a measurement device other than an nanoindentation tester, the measurement processing unit 111 executes measurement control of the measurement unit 108 suitable for the respective device so as to allow for measuring the hardness and loss tangent tan δ of the electrode catalyst layer of the fuel cell.

During the execution of calculation processing, the measurement processing unit 111 executes processing of calculating hardness information, elastic modulus information, and dynamic viscoelasticity information, based on the drive information of the drive unit during the measurement operation acquired by the measurement processing unit 111, and the load information and the displacement information detected by the detection unit when driving the drive unit. The dynamic viscoelasticity information includes storage modulus information, loss modulus information, and loss tangent tan δ information.

Even in a case where the measurement unit 108 is a measurement device other than an nanoindentation tester, when the measurement unit 108 requires measurement control, the measurement processing unit 111 may execute measurement control of the measurement unit 108 suitable for the respective device to allow for measuring hardness and loss tangent tan δ of the electrode catalyst layer of the fuel cell. Even in a case where the measurement unit 108 is a measurement device other than an nanoindentation tester, when calculation processing is required, the measurement processing unit 111 may calculate hardness information and loss tangent tan δ information.

The acquisition unit 112 executes processing of acquiring the hardness information and loss tangent tan δ information of the electrode catalyst layer of the fuel cell, as calculated by the measurement processing unit 111.

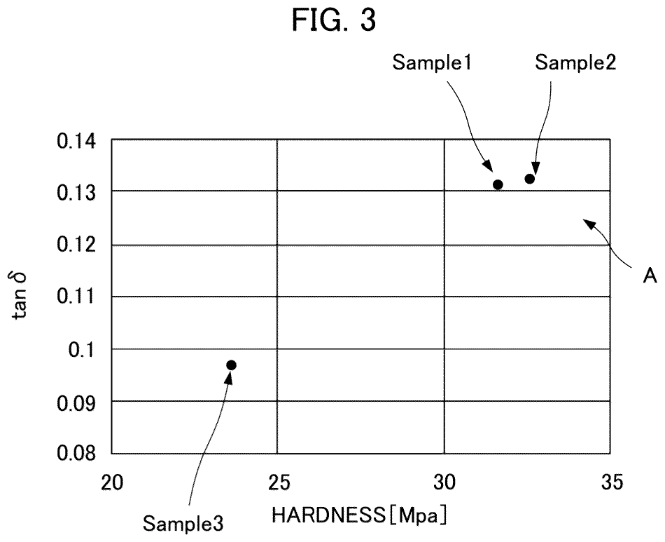

The crack occurrence rate estimation unit 113 executes mapping processing and crack occurrence rate estimation processing. During the execution of mapping processing, the crack occurrence rate estimation unit 113 maps the hardness information and loss tangent tan δ information acquired by the acquisition unit 112 onto a correlation map, in which the vertical axis represents the loss tangent tan δ and the horizontal axis represents hardness, as illustrated in FIG. 3. FIG. 3 is an example of a graph mapped based on the hardness and tan δ acquired by measuring the same sample using the measurement unit 108. In this graph, the vertical axis represents tan δ, and the horizontal axis represents hardness [MPa]. The example illustrated in FIG. 3 indicates Sample 1 with a crack occurrence rate of 0.09%, Sample 2 with a crack occurrence rate of 0.728, and Sample 3 with a crack occurrence rate of 13.65%.

The water-to-alcohol ratio and the proportion of carbon solids in the electrode layer were kept the same in the compositions of the catalyst inks for Samples 1 to 3, and the hardness and tan δ were adjusted by altering the solvent ratio of the catalyst inks and the type of carbon included in the catalyst inks for Samples 1 to 3.

The solvents for each of Samples 1 to 3 were composed of pure water, ethanol, and 1-propanol. The ratio of pure water, ethanol, and 1-propanol in the solvent of the ink for Sample 1 was set to 50:40:10. The ratio of pure water, ethanol, and 1-propanol in the solvent of the ink for Sample 2 was set to 50:25:25. The ratio of pure water, ethanol, and 1-propanol in the solvent of the ink for Sample 3 was set to 50:25:25. These ratios in the solvents are based on weight percentages.

The type of carbon included in the catalyst ink for Sample 1 was the same as the type of carbon included in the catalyst ink for Sample 2. The type of carbon included in the catalyst ink for Sample 3 was different from the type of carbon included in the catalyst ink for Samples 1 and 2.

During the execution of crack occurrence rate estimation processing, the crack occurrence rate estimation unit 113 acquires the correlation information stored in the storage unit 107. Next, the crack occurrence rate estimation unit 113 estimates the crack occurrence rate, based on the hardness information and the loss tangent tan δ information acquired by the acquisition unit 112, as well as the correlation information. In the present embodiment, the crack occurrence rate estimation unit 113 executes processing of estimating the crack occurrence rate for each measurement point on the correlation map created through the mapping processing, based on the hardness information and the loss tangent tan δ information acquired by the acquisition unit 112 and the pre-established correlation information between hardness, loss tangent tan δ, and crack occurrence rate. The estimated crack occurrence rate is associated with each measurement point on the created correlation map, as illustrated in the correlation map of FIG. 3.

In the present embodiment, the measurement results are mapped on the correlation map, and the crack occurrence rate is estimated for each mapped measurement result, based on the correlation information. This allows for visually confirming the evaluation results, thus improving operational efficiency in evaluation. However, the crack occurrence rate may be directly estimated based on the correlation information without mapping the measurement results on the correlation map.

Conventionally, the crack occurrence rate was confirmed by binarizing the image of a sample after coating on a lightboard. However, through research involving investigation and experimentation, the inventors of the present invention have found a correlation between hardness, loss tangent tan δ, and crack occurrence rate. Specifically, the inventors mapped the measurement results on a graph, in which the horizontal axis represents hardness and the vertical axis represents loss tangent tan δ, examined the correlation with crack occurrence rate, and discovered that there is a correlation between hardness, loss tangent tan δ, and crack occurrence rate.

For example, as illustrated in FIG. 3, it was discovered that the harder the electrode catalyst layer of the fuel cell and the higher the loss tangent tan δ, the lower the crack occurrence rate. In the example illustrated in FIG. 3, it is understood that Sample 3 exhibits a higher crack occurrence rate than Sample 1 or Sample 2 that exhibits a harder electrode catalyst layer of the fuel cell and a higher loss tangent tan δ than those of Sample 3.

Therefore, the correlation information between hardness, tan δ, and crack occurrence rate is acquired in advance, and the hardness and the loss tangent tan δ are obtained through measurement, whereby the crack occurrence rate of the electrode catalyst layer of the fuel cell can be evaluated without requiring confirmation using the conventional method described above.

Since there is a correlation between hardness, loss tangent tan δ, and crack occurrence rate, the crack occurrence rate can also be determined based on the range of hardness and loss tangent tan δ corresponding to the crack occurrence rate.

For example, in a case where a crack occurrence rate threshold of 18 is desired for determining the quality of the electrode catalyst layer of the fuel cell, a hardness of 30 MPa and a loss tangent tan δ of 0.12, corresponding to a crack occurrence rate of 18, can serve as the criteria for quality assessment of the electrode catalyst layer of the fuel cell.

Specifically, the measurement results are examined to check whether the hardness is at least 30 MPa and the loss tangent tan δ is at least 0.12. If the hardness is at least 30 MPa and the loss tangent tan δ is at least 0.12, the quality is considered acceptable; if the hardness is not at least 30 MPa and the loss tangent tan δ is not at least 0.12, the quality is considered unacceptable.

In the case where the measurement results indicate the hardness of at least 30 MPa and the loss tangent tan δ of at least 0.12, the measurement points fall within a region A, in which the hardness is at least 30 MPa and the loss tangent tan δ is at least 0.12, as illustrated in the example of FIG. 3. As illustrated in FIG. 3, the measurement results in the region A including Sample 1 and Sample 2 exhibit a crack occurrence rate of less than 1%, while the measurement results outside the region A including Sample 3 exhibit a crack occurrence rate of at least 1%, thus allowing for quality assessment.

The correlation information is, for example, pre-acquired for the same sample by associating the crack occurrence rate, which is pre-confirmed by a conventional method, with the pre-measured hardness and loss tangent tan δ.

The method of acquiring correlation information is not limited to this approach; for example, hardness and loss tangent tan δ are used as input data, while the crack occurrence rate corresponding to the hardness and loss tangent tan δ serves as labels. By using the input data and labels as supervised learning data, machine learning may be employed to construct a learning model as correlation information for evaluating the crack occurrence rate corresponding to the hardness and loss tangent tan δ as the input data.

### <Electrode Catalyst Layer Evaluation Method>

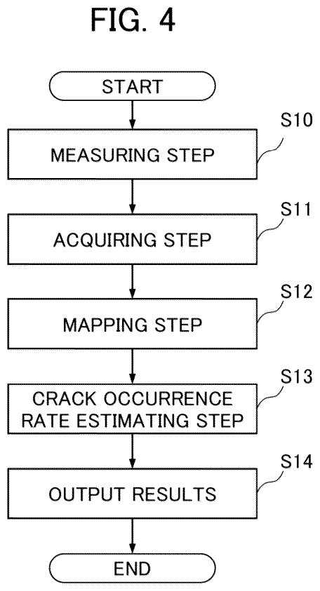

Next, the electrode catalyst layer evaluation method executed by the electrode catalyst layer evaluation device 10 according to the present embodiment will be described with reference to FIG. 4. As illustrated in FIG. 4, the electrode catalyst layer evaluation method includes an acquiring step (Step S11) and a crack occurrence rate estimating step (Step S13). The electrode catalyst layer evaluation method may also include a measuring step (Step S10), a mapping step (Step S12), and a result outputting step (Step S14).

The measuring step (Step S10) is a step of measuring the electrode catalyst layer of the fuel cell. Specifically, this step involves measuring the hardness, elastic modulus, and dynamic viscoelasticity of the electrode catalyst layer of the fuel cell. In the present embodiment, in the measuring step (Step S10), the measurement unit 108 of the electrode catalyst layer evaluation device 10 measures the hardness, elastic modulus, and dynamic viscoelasticity of the electrode catalyst layer of the fuel cell. The dynamic viscoelasticity includes the loss tangent tan δ, as described above.

The acquiring step (Step S11) is a step of acquiring the hardness information and loss tangent tan δ information of the electrode catalyst layer of the fuel cell measured by the measurement unit 108. The acquiring step (Step S11) is executed by the acquisition unit 112 of the electrode catalyst layer evaluation device 10.

The mapping step (Step S12) is a step of creating a correlation map, based on the hardness information and loss tangent tan δ information of the electrode catalyst layer of the fuel cell measured by the measurement unit 108. The mapping step (Step S12) is executed by the crack occurrence rate estimation unit 113 of the electrode catalyst layer evaluation device 10.

As illustrated in FIG. 3, the crack occurrence rate estimating step (Step S13) is a step of estimating and associating the crack occurrence rate, based on the correlation information for each measurement point mapped on the correlation map. The crack occurrence rate estimating step (Step S13) is executed by the crack occurrence rate estimation unit 113 of the electrode catalyst layer evaluation device 10.

The result outputting step (Step S14) is a step of outputting the crack occurrence rate estimated in the crack occurrence rate estimating step (Step S13). For example, in the result outputting step (Step S14), the display of the output unit 106 of the electrode catalyst layer evaluation device 10 may display the correlation map, in which the crack occurrence rate is associated with each measurement point in the crack occurrence rate estimating step (Step S13), or may display a measurement result table listing each measurement point and the corresponding crack occurrence rate. The aspect of outputting the results is not limited to this. The result outputting step (Step S14) is executed by the output unit 106 of the electrode catalyst layer evaluation device 10.

According to the electrode catalyst layer evaluation device 10 of the present embodiment, the following advantages can be achieved. Conventionally, the occurrence of cracks in the membrane electrode of a fuel cell is detected by executing binarization processing on a photograph of the electrode placed on a lightboard, detecting cracks, based on the binarized photograph, and calculating the in-plane crack occupancy rate from the detection results.

The conventional method requires coating and binarization processing on a photograph placed on a lightboard each time confirmation is necessary, resulting in certain material cost and man-hours for calculating the crack occupancy rate. Additionally, the conventional method provides only a qualitative assessment to confirm the crack occurrence rate from the binarized image, and is incapable of conducting quantitative evaluation, potentially leading to variability among operators.

Here, a review was conducted for quantitative evaluation. Factors influencing the occurrence of cracks in the membrane electrode include electrode layer thickness, coarse grains, membrane-electrode interface, and electrode strength. Among these, electrode strength was not adequately quantified for the following reasons, and the degree of the influence thereof was not fully understood.

Known methods of evaluating electrode strength include peel testing and strength assessment using the SAICAS (Surface and Interfacial Cutting Analysis System) method.

However, peel testing involves the problem of weak adhesion between the electrode, membrane, and electrode interface during measurement, which causes significant variability and is prone to measurement errors. Additionally, in the pre-treatment stage, detachment between the electrode, membrane, and electrode interface could occur, compromising the reliability of the data. Consequently, it was challenging to correlate the crack occurrence rate with measurement results. With the strength assessment using the SAICAS method, the only obtainable physical property value was shear strength, which was insufficient for evaluating physical properties other than the presence or absence of cracks in the electrode.

However, the inventors of the present invention have discovered a solution to these issues by mapping the measurement results on a graph, in which the horizontal axis represents hardness on and the vertical axis represents loss tangent tan δ, examining the correlation with the crack occurrence rate, and discovering that there is a correlation between hardness, loss tangent tan δ, and crack occurrence rate, thereby leading to the completion of the present invention. As a result, for example, the electrode strength can be quantified based on highly accurate measurement results from a nanoindentation tester, allowing for estimating the influence of the electrode strength on crack occurrence in the membrane electrode.

The crack occurrence rate can be estimated simply by obtaining the physical property values of the sample; thus, there is no need for conventional confirmation of crack occurrence rate, coating on the membrane, photographing on a lightboard, and applying binarization processing. Therefore, the material cost and man-hours for confirmation were successfully reduced. Furthermore, variability among operators, which was a drawback in conventional crack occurrence rate confirmation, was successfully eliminated, and the accuracy was improved.

The electrode catalyst layer evaluation device 10 according to the present embodiment includes the acquisition unit 112 that acquires the hardness and loss tangent tan δ of the electrode catalyst layer of the fuel cell, and the crack occurrence rate estimation unit 113 that estimates the crack occurrence rate of the electrode catalyst layer, based on the hardness and loss tangent tan δ acquired by the acquisition unit 112.

Thus, the electrode catalyst layer evaluation device 10 according to the present embodiment is capable of reducing cost and man-hours.

With the electrode catalyst layer evaluation device 10 according to the present embodiment, the crack occurrence rate estimation unit 113 estimates the crack occurrence rate of the electrode catalyst layer, based on the pre-established correlation information between the hardness and loss tangent tan δ, and the crack occurrence rate.

Thus, the electrode catalyst layer evaluation device 10 according to the present embodiment is capable of reducing cost and man-hours while conducting more convenient and highly accurate evaluation.

The electrode catalyst layer evaluation device 10 according to the present embodiment further includes the measurement unit 108 that measures the hardness and loss tangent tan δ of the electrode catalyst layer, and the acquisition unit 112 acquires the hardness and loss tangent tan δ from the measurement unit 108.

Thus, the electrode catalyst layer evaluation device 10 according to the present embodiment is capable of reducing cost and man-hours while conducting more convenient and highly accurate evaluation.

In the electrode catalyst layer evaluation device 10 according to the present embodiment, the measurement unit 108 is a nanoindentation tester.

Thus, the electrode catalyst layer evaluation device 10 according to the present embodiment is capable of reducing cost and man-hours while conducting even more convenient and highly accurate evaluation.

The electrode catalyst layer evaluation method according to the present embodiment includes the acquiring step (Step S12) of acquiring the hardness and loss tangent tan δ of the electrode catalyst layer of the fuel cell, and the crack occurrence rate estimating step (Step S14) of estimating the crack occurrence rate of the electrode catalyst layer, based on the hardness and loss tangent tan δ.

Thus, the electrode catalyst layer evaluation method according to the present embodiment is capable of further reducing cost and man-hours.

The program according to the present embodiment causes the electrode catalyst layer evaluation device 10, as a computer, to execute the acquisition function 112 to acquire the hardness and loss tangent tan δ of the electrode catalyst layer of the fuel cell, and the crack occurrence rate estimation function 113 to estimate the crack occurrence rate of the electrode catalyst layer, based on the hardness and loss tangent tan δ.

Thus, the program according to the present embodiment is capable of further reducing cost and man-hours.

### Modified Example

The electrode catalyst layer evaluation device 10 according to the above-described embodiment includes the measurement unit 108, the measurement processing unit 111, the acquisition unit 112, and the crack occurrence rate estimation unit 113 of the control unit 110; however, this is not limiting. For example, a plurality of devices may each include the measurement unit 108, the measurement processing unit 111, the acquisition unit 112, and the crack occurrence rate estimation unit 113 of the control unit 110.

The series of processing described above may be executed by hardware, or alternatively, by software. In other words, the functional configuration illustrated in FIG. 2 is merely illustrative and not restrictive. That is, the electrode catalyst layer evaluation device 10 only needs to include the functionality to execute the entire series of processing described above, and the specific functional blocks used to implement these functions are not limited to the example illustrated in FIG. 2. Each functional block may be configured with hardware alone, software alone, or a combination thereof.

The functional configuration in the present embodiment is implemented by a processor executing computational processing, and the processor applicable in the present embodiment may include a single processor, a multiprocessor, or a multicore processor, or a combination of these processing units with processing circuits such as an Application Specific Integrated Circuit (ASIC) or Field-Programmable Gate Array (FPGA).

In the case of executing the series of processing by software, the program constituting the software is installed on a computer or similar device from a network or storage medium. The computer may be a dedicated computer embedded in specific hardware. Alternatively, the computer may be a general-purpose personal computer capable of executing various functions by installing various programs.

The recording medium containing such a program may be configured as a removable medium separate from the main device, provided to users for program delivery, or may be pre-installed in the main device and provided to users. The removable media may be configured as, for example, magnetic disks (including floppy disks), optical disks, and magneto-optical disks. Optical disks include, for example, CD-ROM (Compact Disk-Read Only Memory), DVD (Digital Versatile Disk), and Blu-ray® Discs. Magneto-optical disks may include Mini-Discs (MDs). The recording media provided pre-installed in the main device may be configured as, for example, the ROM 101 as illustrated in FIG. 1 or a hard disk in the storage unit 107, where the program is recorded.

In this specification, steps for executing the program recorded on a recording medium include not only serial processing in the described order but also processing that may be executed in parallel or individually, rather than strictly sequentially.

While embodiments of the present invention have been described above, these embodiments are merely illustrative and do not limit the technical scope of the present invention. The present invention may take various other embodiments, and numerous modifications, omissions, and substitutions can be made without departing from the scope of the invention. Such embodiments and modifications are included within the scope of the invention described in this specification and within the scope of the invention recited in the claims as well as the equivalents thereof.

What is claimed is:

1. An electrode catalyst layer evaluation device, comprising:
an acquirer configured to acquire hardness and loss tangent tan δ of an electrode catalyst layer of a fuel cell; and
a crack occurrence rate estimator configured to estimate a crack occurrence rate of the electrode catalyst layer, based on the hardness and the loss tangent tan δ acquired by the acquirer.

2. The electrode catalyst layer evaluation device according to claim 1, wherein the crack occurrence rate estimator estimates the crack occurrence rate of the electrode catalyst layer, based on pre-obtained correlation information between the hardness, the loss tangent tan δ, and the crack occurrence rate.

3. The electrode catalyst layer evaluation device according to claim 1, further comprising a measurer configured to measure the hardness and the loss tangent tan δ of the electrode catalyst layer, wherein
the acquirer acquires the hardness and the loss tangent tan δ from the measurer.

4. The electrode catalyst layer evaluation device according to claim 3, wherein the measurer is a nanoindentation tester.

5. An electrode catalyst layer evaluation method comprising:
an acquiring step of acquiring hardness and loss tangent tan δ of an electrode catalyst layer of a fuel cell; and
a crack occurrence rate estimating step of estimating a crack occurrence rate of the electrode catalyst layer, based on the hardness and the loss tangent tan δ.

6. A non-transitory computer-readable storage medium storing a program that is executed by a computer that comprises a processor to control an electrode catalyst layer evaluation device, the program being executable to cause the computer to perform operations comprising:
acquiring hardness and loss tangent tan δ of an electrode catalyst layer of a fuel cell; and
estimating a crack occurrence rate of the electrode catalyst layer, based on the hardness and the loss tangent tan δ.
